(19) United States
(12) Patent Application Publication
(10) Pub. No.: US 2025/0386554 A1
(43) Pub. Date: Dec. 18, 2025

(54) AMBIPOLAR OXIDE SEMICONDUCTOR FERROELECTRIC TRANSISTOR AND MANUFACTURING METHOD THEREOF

(71) Applicant: Taiwan Semiconductor Manufacturing Company, Ltd., Hsinchu (TW)

(72) Inventors: Gerben DOORNBOS, Kessel-Lo (BE); Georgios Vellianitis, Heverlee (BE); Marcus Johannes Henricus Van Dal, Linden (BE); Ken-Ichi GOTO, Hsinchu (TW)

(73) Assignee: Taiwan Semiconductor Manufacturing Company, Ltd., Hsinchu (TW)

(21) Appl. No.: 18/745,251

(22) Filed: Jun. 17, 2024

(51) Int. Cl. H01L 29/78; H01L 21/02; H01L 29/66; H01L 29/786

(52) U.S. Cl. CPC H10D 30/701; H01L 21/02565; H01L 21/02614; H10D 30/6755; H10D 30/6757; H10D 99/00

(57) ABSTRACT

An ambipolar oxide semiconductor ferroelectric transistor (ambipolar OS FeFET) and a manufacturing method thereof are provided. The ambipolar OS FeFET includes a metal gate, a ferroelectric layer and a channel layer. The ferroelectric layer is disposed on the metal gate. The channel layer is disposed on the ferroelectric layer. The channel layer includes a mixture of SnO and SnO2.

### BACKGROUND

The disclosure relates in general to a semiconductor device and a manufacturing method thereof, and more particularly to an ambipolar oxide semiconductor ferroelectric transistor (ambipolar OS FeFET) and a manufacturing method thereof.

Oxide semiconductors (OS) are emerging as channel in back-end of line (BEOL)-compatible thin-film transistors. An OS FeFET is a device combining OS with a ferroelectric (FE) insulator, and provides a useful memory transistor.

Programming/erasing requires a large electric field over the ferroelectric layer. The OS must act as field plate. Conventional OS conduct electrons, but no holes. For positive gate voltage, the OS is populated with electrons, and can act as negatively charged field plate, resulting in effective programming action. For negative gate voltage, the OS is depleted of electrons, but holes do not form, and there is too little positive charge on the OS to act as field plate. Therefore, the conventional OS FeFET could not perform erasing well.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a program procedure performed on an ambipolar oxide semiconductor ferroelectric transistor (ambipolar OS FeFET) according to one embodiment of the present disclosure.

FIG. 2 illustrates an erasing procedure performed on the ambipolar OS FeFET according to one embodiment of the present disclosure.

FIG. 3 illustrates schematized transistor transfer characteristic.

FIG. 4 shows the ambipolar OS FeFET according to another embodiment of the present disclosure.

FIG. 5 shows an ambipolar OS FeFET according to another embodiment of the present disclosure.

FIG. 6 shows an ambipolar OS FeFET according to another embodiment of the present disclosure.

FIG. 7 shows an ambipolar OS FeFET according to another embodiment of the present disclosure.

FIG. 8 shows an ambipolar OS FeFET according to another embodiment of the present disclosure.

FIG. 9 shows an ambipolar OS FeFET according to another embodiment of the present disclosure.

FIG. 10 shows an ambipolar OS FeFET according to another embodiment of the present disclosure.

FIG. 11 shows an ambipolar OS FeFET according to another embodiment of the present disclosure.

FIG. 12 shows a flowchart of a manufacturing method of the ambipolar OS FeFET according to one embodiment of the present disclosure.

FIG. 13 illustrates the manufacturing method of the ambipolar OS FeFET according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

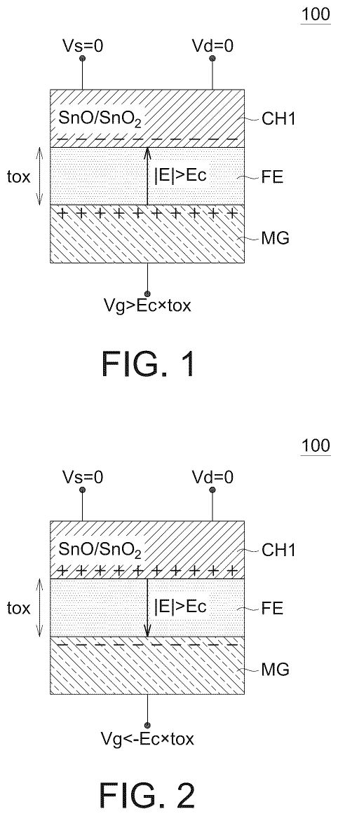

Please refer to FIG. 1, which illustrates a program procedure performed on an ambipolar oxide semiconductor ferroelectric transistor (ambipolar OS FeFET) 100 according to one embodiment of the present disclosure. The ambipolar OS FeFET 100 at least includes a metal gate MG, a ferroelectric layer FE and a channel layer CH1. The ferroelectric layer FE is disposed on the metal gate MG. The channel layer CH1 is disposed on the ferroelectric layer FE. The channel layer FE is composed of a mixture of SnO and SnO2. SnO is a P-type material, meaning it is a good hole-conductor, and SnO2 is an N-type material, meaning it is a good electron conductor.

As shown in the FIG. 1, the gate voltage Vg is, for example, larger than the product of a coercive field Ec and a thickness tox. When the gate voltage Vg applied on the metal gate MG is positive, the source voltage Vs is 0 and the drain voltage Vd is 0, SnO2 in the channel layer CH1 can easily provide electrons. The channel layer CH1 could act as a negatively charged field plate populated with electrons. If the field E is positive and the absolute value thereof is larger than the coercive field Ec, then the program procedure could be worked well.

Please referring to FIG. 2, which illustrates an erasing procedure performed on the ambipolar OS FeFET 100 according to one embodiment of the present disclosure. As shown in the FIG. 2, the gate voltage Vg is, for example, less than the product of the negative value of the coercive field Ec and the thickness tox. When the gate voltage Vg applied on the metal gate MG is negative, the source voltage Vs is 0 and the drain voltage Vd is 0, SnO in the channel layer CH1 can easily provide holes. The channel layer CH1 could act as a positively charged field plate populated with holes. If the field E is negative and the absolute value thereof is larger than the coercive field Ec, then the erasing procedure could be worked well.

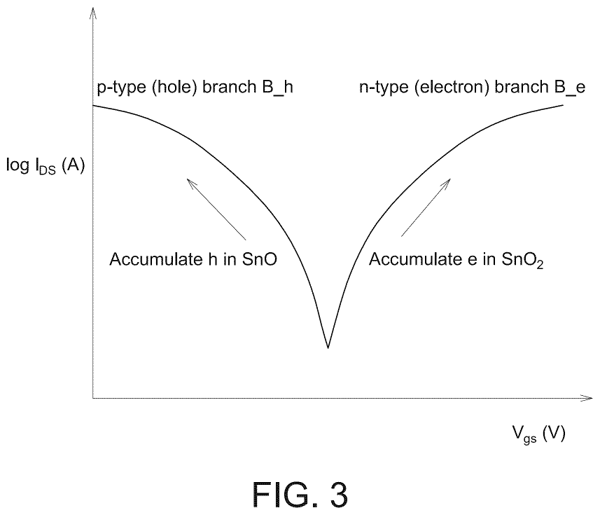

Please refer to FIG. 3, which illustrates schematized transistor transfer characteristic. As shown in the FIG. 3, the gate current is consistently low, implying current flows from source to drain. The curve shows a distinct minimum. Left of this minimum, so for more negative gate voltage, the current increases due to the increase of the hole density, like in a p-channel transistor. Right of this minimum, so for more positive gate voltage, the current increases due to the increase of the electron density like in an n-channel transistor. This combined n-channel and p-channel behavior is specific to ambipolar transistors.

The channel layer CH1 including the mixture of SnO and SnO2 combining with the ferroelectric layer FE will provide efficient program and erase, since the channel layer CH1 acts as the field plate both for the positive gate voltage Vg and the negative gate voltage Vg.

Due to the coexistence of the SnO and the SnO2, there is an electron branch B_e for providing the efficient program procedure, and there is a hole branch B_h for providing the efficient erasing procedure. A read margin RM is larger than 1000, so that the ambipolar OS FeFET 100 could have enough margin to read.

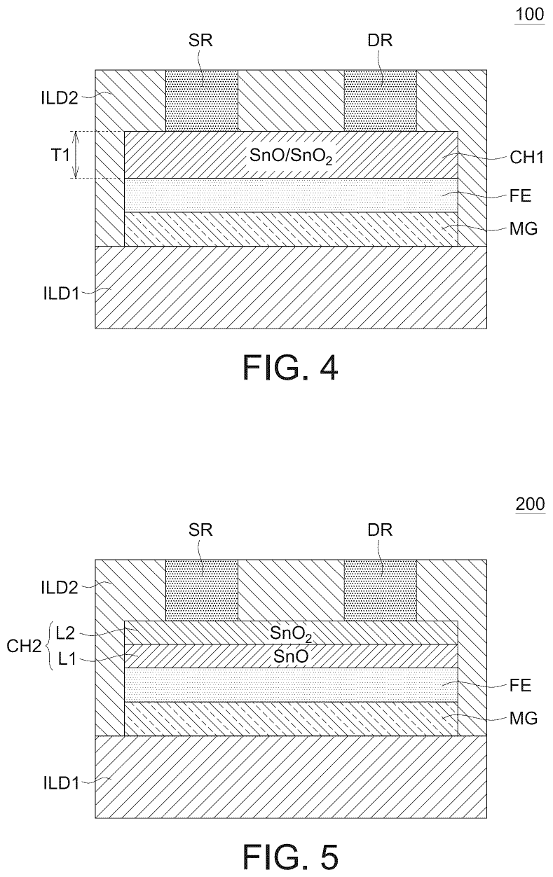

Please refer to FIG. 4, which shows the ambipolar OS FeFET 100 according to one embodiment of the present disclosure. In the ambipolar OS FeFET 100, the metal gate MG is formed on an Inter-layer-dielectric (ILD) layer ILD1. The ferroelectric layer FE is disposed on the metal gate MG. The channel layer CH1 is disposed on the ferroelectric layer FE. A source SR and a drain DR are disposed on the channel layer CH1. An ILD layer ILD2 covers the metal gate MG, the ferroelectric layer FE, the channel layer CH1, the source SR and the drain DR.

A thickness Tl of the channel layer CH1 is equal to or less than 20 nm. For example, the thickness Tl of the channel layer CH1 is between 5 to 20 nm. A ratio of SnO to SnO2 could be controlled by an oxidation procedure and a hydrogenation procedure. For example, the oxidation procedure is used to form SnO2 and the hydrogenation procedure is used to form SnO. The ratio of SnO to SnO2 could be controlled between 1:4 and 4:1, so that the margin to read could be easily adjusted according to the needs. In one embodiment, the crystallinity will enhance the hole-branch B_h (or called p-branch), and the oxygen-exposure will enhance the electron-branch B_e (or called n-branch).

In the channel layer CH1, SnO could be crystalline and SnO2 could be crystalline. Or, in the channel layer CH1, SnO could be amorphous and SnO2 could be crystalline. Or, in the channel layer CH1, SnO could be crystalline and SnO2 could be amorphous. Or, in the channel layer, SnO could be amorphous and SnO2 could be amorphous. The SnO and/or SnO2 could be crystalline or amorphous, so that the manufacturing process is more flexible and easier to control the hole-branch B_h and the electron-branch B_e.

Due to the mixture of SnO and SnO2, the ambipolar OS FeFET 100 has efficient program and erase action. The channel layer CH1 could be populated with holes or electrons, so the ambipolar OS FeFET 100 has a symmetric memory window.

Because SnO could be populated with holes, only the low erase voltage is used for the erasing procedure, and high read margin is maintained.

In another embodiment, the channel layer could be composed of a mixture of any p-type material and any n-type material. Due to the coexistence of the p-type material and any n-type material, there could be a good electron branch for providing the efficient program procedure, and there would be a good hole branch for providing the efficient erasing procedure.

Please refer to FIG. 5, which shows an ambipolar OS FeFET 200 according to another embodiment of the present disclosure. In this embodiment, the channel layer CH2 includes a SnO layer L1 and a SnO2 layer L2. The SnO2 layer L2 is stacked on the SnO layer L1. The thickness of the SnO layer L1 and the thickness of the SnO2 layer L2 could be, for example, identical. Or, the thickness of the SnO layer L1 could be, for example, larger than the thickness of the SnO2 layer L2. Or, the thickness of the SnO layer L1 could be, for example, less than the thickness of the SnO2 layer L2. In one embodiment, the ratio of SnO layer L1 to the SnO2 layer L2 could be controlled between 1:4 and 4:1, so that the margin to read could be easily adjusted according to the needs. In FIG. 5, the SnO layer L1 is closer to the channel FE than the SnO2 layer L2, so more holes could be gathered near the channel FE and the erase procedure could be worked well.

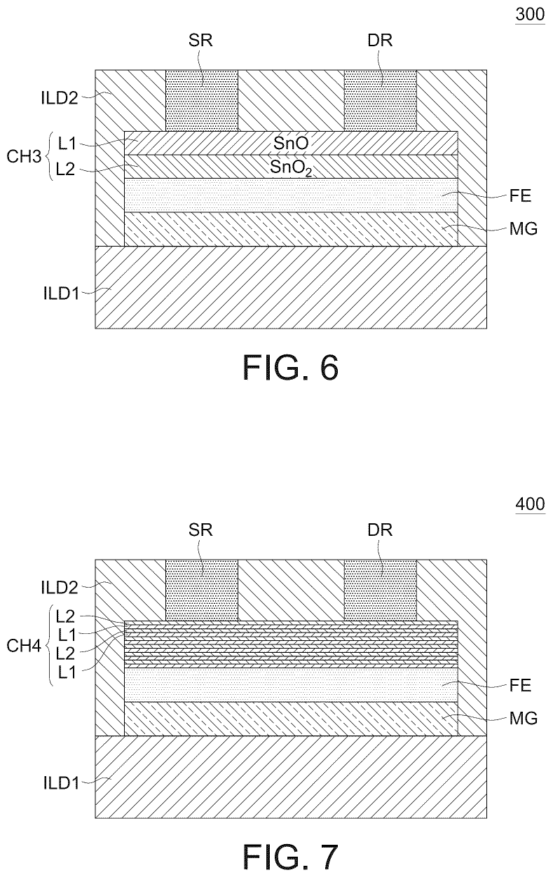

Please refer to FIG. 6, which shows an ambipolar OS FeFET 300 according to another embodiment of the present disclosure. In this embodiment, the channel layer CH3 includes a SnO layer L1 and a SnO2 layer L2. The SnO layer L1 is stacked on the SnO2 layer L2. The thickness of the SnO layer L1 and the thickness of the SnO2 layer L2 could be, for example, identical. Or, the thickness of the SnO layer L1 could be, for example, larger than the thickness of the SnO2 layer L2. Or, the thickness of the SnO layer L1 could be, for example, less than the thickness of the SnO2 layer L2. In FIG. 6, the SnO2 layer L2 is closer to the channel FE than the SnO layer L1, so more electrons could be gathered near the channel FE and the program procedure could be worked well.

Please refer to FIG. 7, which shows an ambipolar OS FeFET 400 according to another embodiment of the present disclosure. In this embodiment, the channel layer CH4 includes a plurality of SnO layers L1 and a plurality of SnO2 layers L2. The SnO2 layers L2 and the SnO layers L1 are alternately stacked. The thickness of each of the SnO layers L1 and the thickness of each of the SnO2 layers L2 could be, for example, identical. Or, the thickness of each of the SnO layers L1 could be, for example, larger than the thickness of each of the SnO2 layers L2. Or, the thickness of each of the SnO layers L1 could be, for example, less than the thickness of each of the SnO2 layers L2. The thicknesses of the SnO layers L1 could be, for example, identical. Or, the thicknesses of the SnO layers L1 could be, for example, different. The thicknesses of the SnO2 layers L2 could be, for example, identical. Or, the thicknesses of the SnO2 layers L2 could be, for example, different. The bottom of the channel layer CH4 could be, for example, the SnO layer L1. Or, the bottom of the channel layer CH4 could be, for example, the SnO2 layer L2. The top of the channel layer CH4 could be, for example, the SnO2 layer L2. Or, the top of the channel layer CH4 could be, for example, the SnO layer L1. The number of the SnO layers L1 and the number of the SnO2 layers L2 could be, for example, identical. Or, the number of the SnO layers L1 and the number of the SnO2 layers L2 could be, for example, different. In one embodiment, the channel layer CH4 could include two SnO layers L1 and one SnO2 layer L2 disposed therebetween. Or, the channel layer CH4 could include two SnO2 layers L2 and one SnO2 layer L1 disposed therebetween. The staggered stacking of the SnO layers L1 and the SnO2 layers L2 is used to disperse the holes and the electrons.

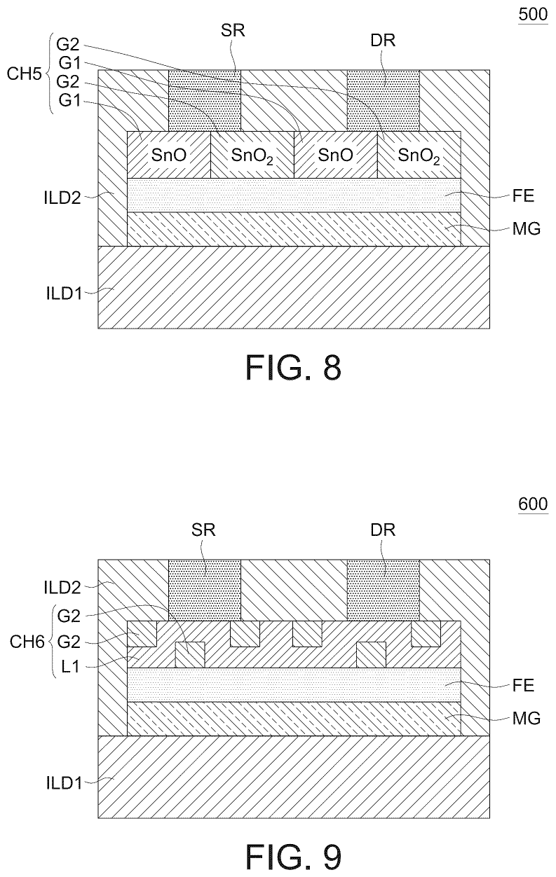

Please refer to FIG. 8, which shows an ambipolar OS FeFET 500 according to another embodiment of the present disclosure. In this embodiment, the channel layer CH5 includes a plurality of SnO grains G1 and a plurality of SnO2 grains G2. The SnO grains G1 and the SnO2 grains G2 are alternately disposed. For example, as shown in the FIG. 8, the arrangement of the SnO grains G1 and the SnO2 grains G2 is “the SnO grain G1/SnO2 grain G2/the SnO grain G1/the SnO2 grain G2”. Or, in another embodiment, the arrangement of the SnO grains G1 and the SnO2 grains G2 could be “the SnO2 grain G2/SnO grain G1/the SnO2 grain G2/the SnO grain G1”. Or, in another embodiment, the arrangement of the SnO grains G1 and the SnO2 grains G2 could be “the SnO2 grain G2/the SnO grain G1/SnO2 grain G2/the SnO grain G1/the SnO2 grain G2”. Or, in another embodiment, the arrangement of the SnO grains G1 and the SnO2 grains G2 could be “SnO grain G1/the SnO2 grain G2/the SnO grain G1/the SnO2 grain G2/the SnO grain G1”. The width of each of the SnO grains G1 and the width of each of the SnO2 grains G2 could be, for example, identical. Or, the width of each of the SnO grains G1 could be, for example, larger than the width of each of the SnO2 grains G2. Or, the width of each of the SnO grains G1 could be, for example, less than the width of each of the SnO2 grains G2. The widths of the SnO grains G1 could be, for example, identical. Or, the widths of the SnO grains G1 could be, for example, different. The widths of the SnO2 grains G2 could be, for example, identical. Or, the widths of the SnO2 grains G2 could be, for example, different.

The source SR covers, for example, at least one of the SnO grains G1 and at least one of the SnO2 grains G2. The drain DR covers, for example, at least one of the SnO grains G1 and at least one of the SnO2 grains G2. At least one of the SnO grains G1 and at least one of the SnO2 grains G2 are disposed, for example, between the locations of the source SR and the drain DR. In another embodiment, the source SR could cover the SnO grain G1 only, and the drain DR could cover the SnO grain G1 only. In another embodiment, the source SR could cover the SnO2 grain G2 only, and the drain DR could cover the SnO2 grain G2 only. In another embodiment, the source SR could cover the SnO grain G1 only, and the drain DR could cover the SnO2 grain G2 only. In another embodiment, the source SR could cover the SnO2 grain G2 only, and the drain DR could cover the SnO grain G1 only.

Please refer to FIG. 9, which shows an ambipolar OS FeFET 600 according to another embodiment of the present disclosure. The channel layer CH6 includes a SnO layer L1 and a plurality of SnO2 grains G2. The SnO2 grains G2 are embedded in the SnO layer L1. The thickness of the SnO layer L1 could be, for example, larger than the thickness of each of the SnO2 grains G2. The thicknesses of the SnO2 grains G2 could be, for example, identical. The thickness of the SnO2 grains G2 could be, for example, different. The widths of the SnO2 grains G2 could be, for example, identical. The widths of the SnO2 grains G2 could be, for example, different. The source SR covers, for example, part of the SnO layer L1 and at least one of the SnO2 grains G2. The drain DR covers, for example, part of the SnO layer L1 and at least one of the SnO2 grains G2. Part of the SnO layer L1 and at least one of the SnO2 grains G2 are disposed, for example, between the locations of the source SR and the drain DR. In another embodiment, the source SR could cover the SnO layer L1 only. Or, in other embodiment, the source SR could cover the SnO2 grain G2 only. Or, in another embodiment, the drain DR could cover the SnO layer L1 only. Or, in other embodiment, the drain DR could cover the SnO2 grain G2 only.

Please refer to FIG. 10, which shows an ambipolar OS FeFET 700 according to another embodiment of the present disclosure. The channel layer CH7 includes a SnO2 layer L2 and a plurality of SnO grains G1. The SnO grains G1 are embedded in the SnO2 layer L2. The thickness of the SnO2 layer L2 could be, for example, larger than the thickness of each of the SnO grains G1. The thicknesses of the SnO grains G1 could be, for example, identical. The thickness of the SnO grains G1 could be, for example, different. The widths of the SnO grains G1 could be, for example, identical. Or, the widths of the SnO grains G1 could be, for example, different. The source SR covers, for example, part of the SnO2 layer L2 and at least one of the SnO grains G1. The drain DR covers, for example, part of the SnO2 layer L2 and at least one of the SnO grains G1. Part of the SnO2 layer L2 and at least one of the SnO grains G1 are disposed, for example, between the locations of the source SR and the drain DR. In another embodiment, the source SR could cover the SnO layer L1 only. Or, in other embodiment, the source SR could cover the SnO2 grain G2 only. Or, in another embodiment, the drain DR could cover the SnO layer L1 only. Or, in other embodiment, the drain DR could cover the SnO2 grain G2 only.

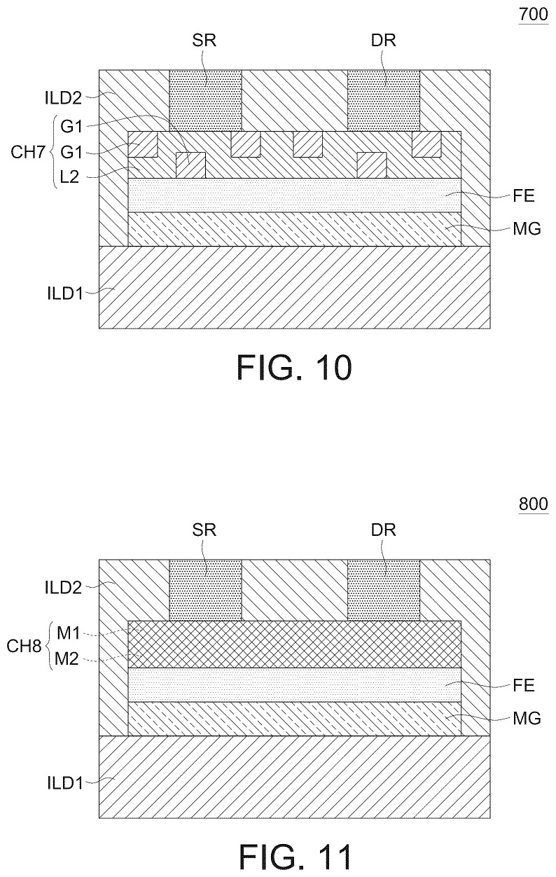

Please refer to FIG. 11, which shows an ambipolar OS FeFET 800 according to another embodiment of the present disclosure. The channel layer CH8 includes a microscopic mixture of SnO and SnO2. This means, individual phases of SnO and SnO2 are not spatially separated as in FIGS. 5-10, but the phases are intermixed; a fraction of the Sn atoms are in the +2 oxidation state (Sn²⁺, as in SnO), and a fraction of the Sn atoms are in the +4 oxidation state (Sn⁴⁺, as in SnO2). A ratio of concentrations of Sn²⁺ to Sn⁴⁺ could be, for example, between 1:4 and 4:1.

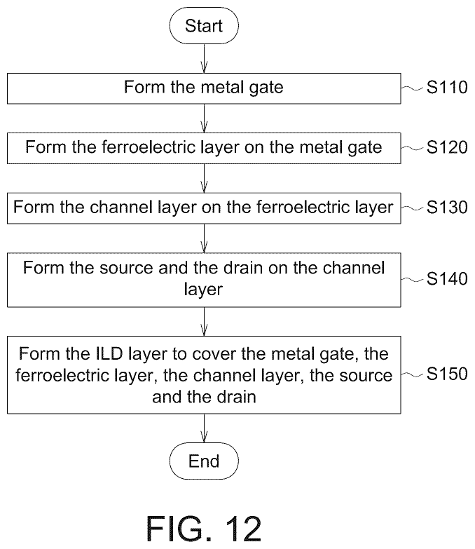

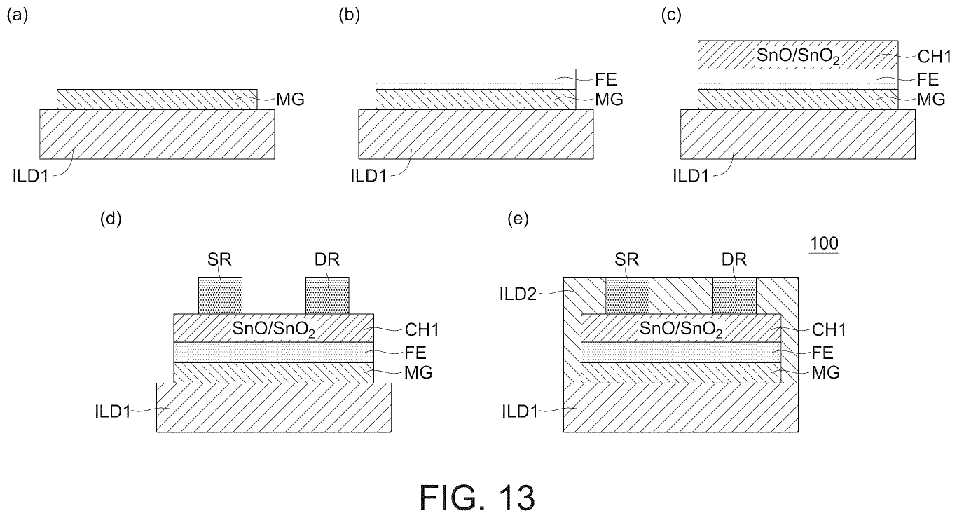

Please refer to FIGS. 12 and 13. FIG. 12 show a flowchart of a manufacturing method of the ambipolar OS FeFET 100 according to one embodiment of the present disclosure. FIG. 13 illustrates the manufacturing method of the ambipolar OS FeFET 100 according to one embodiment of the present disclosure. The manufacturing method of the ambipolar OS FeFET 100 includes, for example, steps S110 to S150.

In the step S110, as shown in the drawing (a) of the FIG. 12, the metal gate MG is formed on the ILD layer ILD1. The material of the metal gate MG is, for example, tungsten (W), ruthenium (Ru), cobalt (Co), copper (Cu), aluminum (Al), nickel (Ni), gold (Au), silver (Ag), molybdenum (Mo), titanium nitride (TiN), tantalum nitride (TaN), the like, or a combination thereof.

In this step, the material(s) of the metal gate MG may be deposited on the ILD layer ILD1. The metal gate MG may be deposited by any suitable method, such as chemical oxidation, thermal oxidation, atomic layer deposition (ALD), chemical vapor deposition (CVD), physical vapor deposition (PVD), plating, other suitable methods, or combinations thereof. Then, the material(s) of the metal gate MG is/are patterned to define the stack on the ILD layer ILD1.

Then, in the step S120, as shown in the drawn (b) of the FIG. 12, the ferroelectric layer FE is formed on the metal gate MG. The material of the ferroelectric layer FE is, for example, selected to have a suitable crystallization temperature. For example, a hafnium oxide based material (HfOx), a zirconium oxide based material (ZrOx), a ternary hafnium-zirconium oxide based material (HfZrOx, HZO), may be used to form the ferroelectric layer FE, and other ferroelectric materials may also be used. For example, the ferroelectric materials such aluminum nitride (AlN), yttrium oxide (Y2O3), or the like may also be used. Then, the material(s) of the ferroelectric layer FE is/are patterned to define the stack on the metal gate MG.

In this step, the material(s) of the ferroelectric layer FE may be deposited on the metal gate MG. The ferroelectric layer FE could be formed, for example, by using atomic layer deposition (ALD), which is capable of accurately control how many atomic layers of the ferroelectric layer FE are formed, and hence is capable of accurately control the thickness of the ferroelectric layer FE. Or, other deposition methods such as chemical vapor deposition (CVD) or physical vapor deposition (PVD) could be used.

Next, in the step S130, as shown in the drawing (c) of the FIG. 12, the channel layer CH1 composed of the mixture of SnO and SnO2 is formed on the ferroelectric layer FE. The channel layer CH1 may be formed using atomic layer deposition (ALD), physical vapor deposition (PVD) (sputtering), chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), or atomic layer CVD (ALCVD). Deposition conditions (temperature, ambient, pressure, target, precursor, . . . ) determine the initial SnO:SnO2 ratio. A post-deposition anneal (PDA) in a oxygen-containing ambient may be done to increase the concentration of SnO2. A post-deposition anneal (PDA) in a hydrogen-containing ambient may be done to increase the concentration of SnO. A post-deposition anneal (PDA) in vacuum or ultra-high vacuum (UHV) may be done to increase the concentration of SnO.

For forming the stack that the SnO2 layer L2 is stacked on the SnO layer L1 (as shown in the FIG. 5), the SnO layer L1 is formed first and then the oxidation procedure is performed to form the SnO2 layer L2 sitting on the SnO layer L1.

For forming the stack that the SnO2 layer L2 is stacked on the SnO layer L1 (as shown in the FIG. 6), the SnO layer L1 is formed first and then the hydrogenation procedure is performed to form the SnO layer L1 sitting on the SnO2 layer L2.

Afterwards, in the step S140, as shown in the drawing (d) of the FIG. 12, the source SR and the drain DR are formed on the channel layer CH1. The source SR and the drain DR may be metallic regions in direct contact with the channel layer CH1. SR and DR may comprise TiN, W, TaN, Cu, Ni, Pd, Pt, Ru, Ir, W, any other metal, or combinations thereof. The source SR and drain DR may be heavily doped semiconducting regions in direct contact with the channel layer CH1. SR and DR may comprise indium oxide (In2O3), tungsten-doped indium oxide (In2O3:W, or IWO), tin-doped indium oxide (In2O3:Sn, or ITO), or combinations thereof.

Next, in the step S150, as shown in the drawing (e) of the FIG. 12, the ILD layer ILD2 is formed to cover the metal gate MG, the ferroelectric layer FE, the channel layer CH1, the source SR and the drain DR. The ILD layer ILD2 is, for example, silicon oxide (SiO), silicon oxycarbide (SiCO), Silicon carbon nitride (SiCN), silicon oxycarbonitride (SiCON), silicon oxynitride (SiNO), silicon nitride (SIN), the like or a combination thereof.

The ILD layer ILD2 may be formed by PECVD (plasma enhanced CVD), FCVD (flowable CVD), or other suitable methods. Based on above, the ambipolar OS FeFET 100 is formed.

According to the embodiments described above, the mixture of SnO and SnO2 is used to form the channel layer CH1 (or CH2 to CH8), so the ambipolar OS FeFET 100 (or 200 to 800) has efficient program and erase action. The channel layer CH1 (or CH2 to CH8) could be populated with holes or electrons, so the ambipolar OS FeFET 100 (or 200 to 800) has the symmetric memory window. Moreover, because SnO could be populated with holes, only low erase voltage is needed for the erasing procedure. Further, the high read margin is maintained.

According to one example embodiment, an ambipolar oxide semiconductor ferroelectric transistor (ambipolar OS FeFET) is provided. The ambipolar OS FeFET includes a metal gate, a ferroelectric layer and a channel layer. The ferroelectric layer is disposed on the metal gate. The channel layer is disposed on the ferroelectric layer. The channel layer includes a mixture of SnO and SnO2.

Based on the ambipolar oxide semiconductor ferroelectric transistor described in the previous embodiments, a thickness of the channel layer is equal to or less than 20 nm.

Based on the ambipolar oxide semiconductor ferroelectric transistor described in the previous embodiments, a thickness of the channel layer is between 5 to 20 nm.

Based on the ambipolar oxide semiconductor ferroelectric transistor described in the previous embodiments, the channel layer includes a SnO layer and a SnO2 layer. The SnO2 is stacked on the SnO layer.

Based on the ambipolar oxide semiconductor ferroelectric transistor described in the previous embodiments, the channel layer includes a SnO2 layer and a SnO layer. The SnO layer is stacked on the SnO2 layer.

Based on the ambipolar oxide semiconductor ferroelectric transistor described in the previous embodiments, the channel layer includes a plurality of SnO2 layers and a plurality of SnO layers. The SnO2 layers and the SnO layers are alternately stacked.

Based on the ambipolar oxide semiconductor ferroelectric transistor described in the previous embodiments, the channel layer includes a plurality of SnO grains and a plurality of SnO2 grains. The SnO grains and the SnO2 grains are alternately disposed.

Based on the ambipolar oxide semiconductor ferroelectric transistor described in the previous embodiments, the channel layer includes a SnO layer and a plurality of SnO2 grains. The SnO2 grains are embedded in the SnO layer.

Based on the ambipolar oxide semiconductor ferroelectric transistor described in the previous embodiments, the channel layer includes a SnO2 layer and a plurality of SnO grains. The SnO grains are embedded in the SnO2 layer.

Based on the ambipolar oxide semiconductor ferroelectric transistor described in the previous embodiments, the channel layer includes mixture of SnO and SnO2, SnO and SnO2 phases are intermixed and are not spatially separate. A fraction of Sn-atoms are in the +2, and a fraction of Sn-atoms are in the +4 oxidation state.

Based on the ambipolar oxide semiconductor ferroelectric transistor described in the previous embodiments, a ratio of SnO to SnO2 is between 1:4 and 4:1.

Based on the ambipolar oxide semiconductor ferroelectric transistor described in the previous embodiments, in the channel layer, SnO is crystalline, and SnO2 is crystalline.

Based on the ambipolar oxide semiconductor ferroelectric transistor described in the previous embodiments, in the channel layer, SnO is amorphous, and SnO2 is crystalline.

Based on the ambipolar oxide semiconductor ferroelectric transistor described in the previous embodiments, in the channel layer, SnO is crystalline, and SnO2 is amorphous.

Based on the ambipolar oxide semiconductor ferroelectric transistor described in the previous embodiments, in the channel layer, SnO is amorphous, and SnO2 is amorphous.

According to one example embodiment, an ambipolar oxide semiconductor ferroelectric transistor (ambipolar OS FeFET) is provided. The ambipolar OS FeFET includes a metal gate, a ferroelectric layer and a channel layer. The ferroelectric layer is disposed on the metal gate. The channel layer is disposed on the ferroelectric layer. The channel layer includes a mixture of p-type material and n-type material.

Based on the ambipolar oxide semiconductor ferroelectric transistor described in the previous embodiments, a thickness of the channel layer is equal to or less than 20 nm.

Based on the ambipolar oxide semiconductor ferroelectric transistor described in the previous embodiments, the channel layer is a bilayer with n-type material sitting on p-type material.

According to one example embodiment, a manufacturing method of an ambipolar oxide semiconductor ferroelectric transistor (ambipolar OS FeFET) is provided. The manufacturing method of the ambipolar OS FeFET includes the following steps: forming a metal gate; forming a ferroelectric layer on the metal gate; and forming a channel layer on the ferroelectric layer, wherein the channel layer includes a mixture of SnO and SnO2.

Based on manufacturing method of the ambipolar oxide semiconductor ferroelectric transistor described in the previous embodiments, in the step of forming the channel, an oxidation procedure is used to form SnO2 and a hydrogenation procedure is used to form SnO.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An ambipolar oxide semiconductor ferroelectric transistor (ambipolar OS FeFET), comprising:
a metal gate;
a ferroelectric layer, disposed on the metal gate; and
a channel layer, disposed on the ferroelectric layer, wherein the channel layer includes a mixture of SnO and SnO2.

2. The ambipolar oxide semiconductor ferroelectric transistor according to claim 1, wherein a thickness of the channel layer is equal to or less than 20 nm.

3. The ambipolar oxide semiconductor ferroelectric transistor according to claim 1, wherein a thickness of the channel layer is between 5 to 20 nm.

4. The ambipolar oxide semiconductor ferroelectric transistor according to claim 1, wherein the channel layer includes:
a SnO layer; and
a SnO2 layer, stacked on the SnO layer.

5. The ambipolar oxide semiconductor ferroelectric transistor according to claim 1, wherein the channel layer includes:
a SnO2 layer; and
a SnO layer, stacked on the SnO2 layer.

6. The ambipolar oxide semiconductor ferroelectric transistor according to claim 1, wherein the channel layer includes:
a plurality of SnO2 layers; and
a plurality of SnO layers, wherein the SnO2 layers and the SnO layers are alternately stacked.

7. The ambipolar oxide semiconductor ferroelectric transistor according to claim 1, wherein the channel layer includes:
a plurality of SnO grains; and
a plurality of SnO2 grains, wherein the SnO grains and the SnO2 grains are alternately disposed.

8. The ambipolar oxide semiconductor ferroelectric transistor according to claim 1, wherein the channel layer includes:
a SnO layer; and
a plurality of SnO2 grains, embedded in the SnO layer.

9. The ambipolar oxide semiconductor ferroelectric transistor according to claim 1, wherein the channel layer includes:
a SnO2 layer; and
a plurality of SnO grains, embedded in the SnO2 layer.

10. The ambipolar oxide semiconductor ferroelectric transistor according to claim 1, wherein the channel layer includes:
a plurality of Sn atoms in the +2 oxidation state; and
a plurality of Sn atoms in the +4 oxidation state, forming a layer where SnO and SnO2 are intermixed.

11. The ambipolar oxide semiconductor ferroelectric transistor according to claim 1, wherein a ratio of SnO to SnO2 is between 1:4 and 4:1.

12. The ambipolar oxide semiconductor ferroelectric transistor according to claim 1, wherein in the channel layer, SnO is crystalline, and SnO2 is crystalline.

13. The ambipolar oxide semiconductor ferroelectric transistor according to claim 1, wherein in the channel layer, SnO is amorphous, and SnO2 is crystalline.

14. The ambipolar oxide semiconductor ferroelectric transistor according to claim 1, wherein in the channel layer, SnO is crystalline, and SnO2 is amorphous.

15. The ambipolar oxide semiconductor ferroelectric transistor according to claim 1, wherein in the channel layer, SnO is amorphous, and SnO2 is amorphous.

16. An ambipolar oxide semiconductor ferroelectric transistor (ambipolar OS FeFET), comprising:
a metal gate;
a ferroelectric layer, disposed on the metal gate; and
a channel layer, disposed on the ferroelectric layer, wherein the channel layer includes a mixture of p-type material and n-type material.

17. The ambipolar oxide semiconductor ferroelectric transistor according to claim 16, wherein a thickness of the channel layer is equal to or less than 20 nm.

18. The ambipolar oxide semiconductor ferroelectric transistor according to claim 16, wherein the channel layer is a bilayer with n-type material sitting on p-type material.

19. A manufacturing method of an ambipolar oxide semiconductor ferroelectric transistor (ambipolar OS FeFET), comprising:
forming a metal gate;
forming a ferroelectric layer on the metal gate; and
forming a channel layer on the ferroelectric layer, wherein the channel layer includes a mixture of SnO and SnO2.

20. The manufacturing method of the ambipolar oxide semiconductor ferroelectric transistor according to claim 19, wherein in the step of forming the channel, an oxidation procedure is used to form SnO2 and a hydrogenation procedure is used to form SnO.
